(19) United States
(12) Patent Application Publication
(10) Pub. No.: US 2024/0234218 A9
(43) Pub. Date: Jul. 11, 2024

(54) METHOD FOR MANUFACTURING SUBSTRATE AND METHOD FOR MANUFACTURING SEMICONDUCTOR DEVICE

(71) Applicant: Mitsubishi Electric Corporation, Tokyo (JP)

(72) Inventors: Mamoru MATSUO, Tokyo (JP); Kenta NAKAHARA, Tokyo (JP); Keiichi NAKAMURA, Tokyo (JP)

(73) Assignee: Mitsubishi Electric Corporation, Tokyo (JP)

(21) Appl. No.: 18/556,695

(22) PCT Filed: Oct. 5, 2021
(86) PCT No.: PCT/JP2021/036864

§ 371 Date: Oct. 23, 2023

(51) Int. Cl. H01L 21/66

(52) U.S. Cl. CPC H01L 22/12

(57) ABSTRACT

A method for manufacturing a substrate according to the first disclosure includes immersing a substrate on which a plurality of circuit patterns are formed in pure water or a corrosive solution, applying voltage between the plurality of circuit patterns in a state in which the substrate is immersed in the pure water or the corrosive solution and determining the substrate to be a defective product when a tree is generated in the plurality of circuit patterns due to the voltage application and determining the substrate to be a non-defective product when the tree is not generated.

### FIELD

The present disclosure relates to a method for manufacturing a substrate and a method for manufacturing a semiconductor device.

### BACKGROUND

An electrochemical migration evaluation system is disclosed in PTL 1. The evaluation system includes a thermo-hygrostat that stores an electrode for which electrochemical migration (ECM) is evaluated, and a power source device that applies voltage between electrodes. The evaluation system also includes impedance calculation means, evaluation means, and an image capturing device. The impedance calculation means measures current flowing between the electrodes and calculates impedance between the electrodes based on a result of the measurement. The evaluation means evaluates ECM between the electrodes based on a result of the impedance calculation. The image capturing device captures images of surfaces of the electrodes.

### CITATION LIST

### Patent Literature

[PTL 1] JP 2011-153886 A

### SUMMARY

### Technical Problem

The evaluation system of PTL 1 needs measurement by using an impedance detection circuit to perform defect detection. Thus, defect detection potentially cannot be easily performed.

The present disclosure is intended to obtain a method for manufacturing a substrate and a method for manufacturing a semiconductor device with which defect detection can be easily performed.

### Solution to Problem

A method for manufacturing a substrate according to the first disclosure includes immersing a substrate on which a plurality of circuit patterns are formed in pure water or a corrosive solution; applying voltage between the plurality of circuit patterns in a state in which the substrate is immersed in the pure water or the corrosive solution; and determining the substrate to be a defective product when a tree is generated in the plurality of circuit patterns due to the voltage application and determining the substrate to be a non-defective product when the tree is not generated.

A method for manufacturing a semiconductor device according to the second disclosure includes immersing a substrate on which a plurality of circuit patterns are formed in pure water or a corrosive solution; applying voltage between the plurality of circuit patterns in a state in which the substrate is immersed in the pure water or the corrosive solution; determining the substrate to be a defective product when a tree is generated in the plurality of circuit patterns due to the voltage application and determining the substrate to be a non-defective product when the tree is not generated; and mounting a semiconductor chip on the substrate determined to be a non-defective product.

### Advantageous Effects of Invention

With the method for manufacturing a substrate according to the first disclosure and the method for manufacturing a semiconductor device according to the second disclosure, defect detection can be easily performed based on presence or absence of the tree.

### BRIEF DESCRIPTION OF DRAWINGS

FIG. 1 is a plan view of a substrate examination device according to Embodiment 1.

FIG. 2 is a flowchart illustrating a method for manufacturing a semiconductor device according to Embodiment 1.

FIG. 3 is a diagram illustrating an example of a tree.

FIG. 4 is a cross-sectional view of a semiconductor device according to Embodiment 1.

FIG. 5 is a flowchart illustrating a method for manufacturing a semiconductor device according to Embodiment 2.

### DESCRIPTION OF EMBODIMENTS

A method for manufacturing a substrate and a method for manufacturing a semiconductor device according to each embodiment will be described with reference to drawings. Identical or corresponding constitutional elements are given the same reference numerals, and the repeated description of such constitutional elements may be omitted.

### Embodiment 1

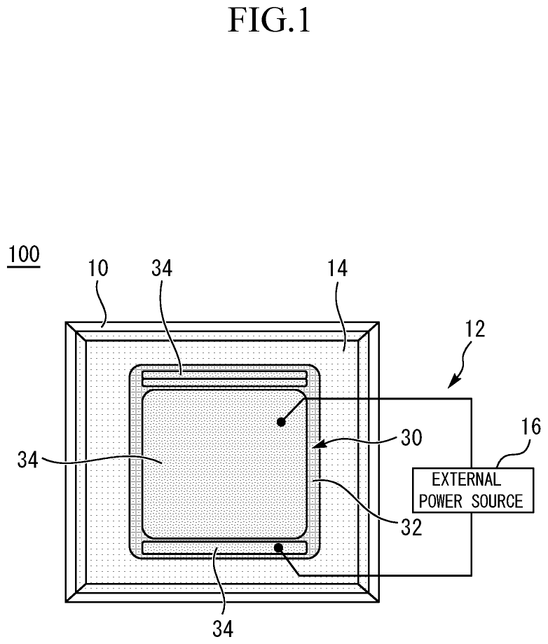

FIG. 1 is a plan view of a substrate examination device 100 according to Embodiment 1. The examination device 100 includes a case 10 that holds immersion liquid 14 such as pure water or a corrosive solution, and a voltage application circuit 12 that applies voltage to an examination target. The case 10 is insulative and formed of plastic or the like. In the present embodiment, pure water is used as the immersion liquid 14.

The examination target is a substrate 30. The substrate 30 is also called an insulative substrate or a ceramic substrate. The substrate 30 includes an insulating layer 32 and a plurality of circuit patterns 34 formed on a surface of the insulating layer 32. The insulating layer 32 is formed of ceramic such as SiN. The plurality of circuit patterns 34 are formed by joining metal layers of Cu, Al, or the like to the insulating layer 32. The metal layers may be formed on both surfaces of the insulating layer 32. Among the metal layers, metal layers formed on the surface of the insulating layer 32 are referred to as circuit patterns 34. The surface of the insulating layer 32 is a surface on which semiconductor chips are mounted.

The plurality of circuit patterns 34 are separated from one another. The voltage application circuit 12 is a circuit for applying voltage between the plurality of circuit patterns 34 from an external power source 16 in a state in which the substrate 30 is immersed in the immersion liquid 14.

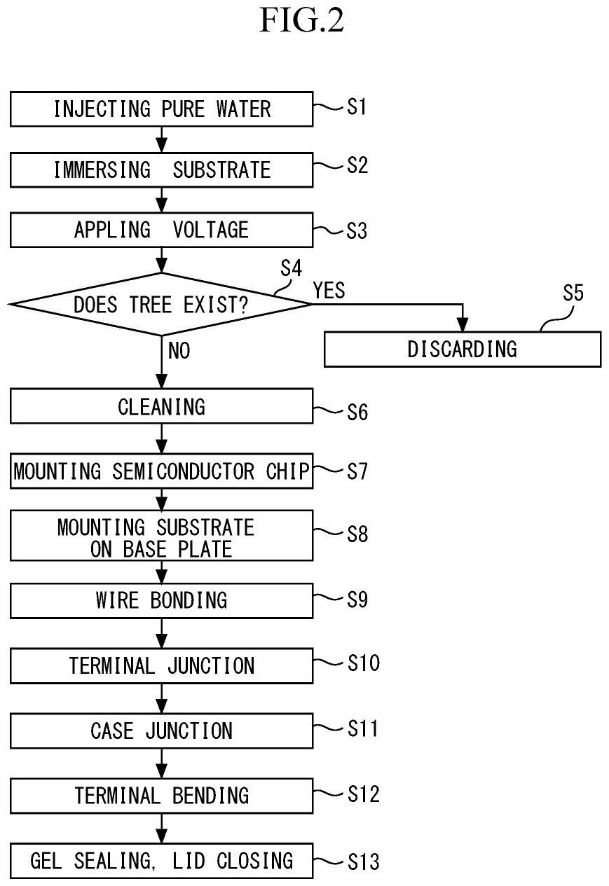

FIG. 2 is a flowchart illustrating a method for manufacturing a semiconductor device according to Embodiment 1. The method for manufacturing a semiconductor device by using the examination device 100 will be described with reference to FIG. 2. First, as step 1, pure water is injected into the case 10. Subsequently, as step 2, the substrate 30 is immersed in the pure water. In this case, the entire substrate 30 is preferably immersed in the pure water.

Subsequently, as step 3, voltage is applied between the plurality of circuit patterns 34 in a state in which the substrate 30 is immersed in the pure water. In this case, the voltage application from the external power source 16 is performed while electrodes of the voltage application circuit 12 are in contact with the circuit patterns 34. The inter-electrode voltage is, for example, 20 V.

Subsequently, as step 4, presence or absence of a tree is checked. At step 3, metal of the circuit patterns 34 reacts with water and electrochemical migration occurs in some cases. In such a case, metal ions are generated on the anode side, and metal is deposited on the cathode side. As a result, a tree is observed. In this manner, presence or absence of ion migration occurrence can be checked based on presence or absence of a tree. A tree generation tendency typically corresponds to a voltage resistance degradation tendency of the insulative substrate. This is because voltage resistance typically decreases as a product is exposed at higher humidity.

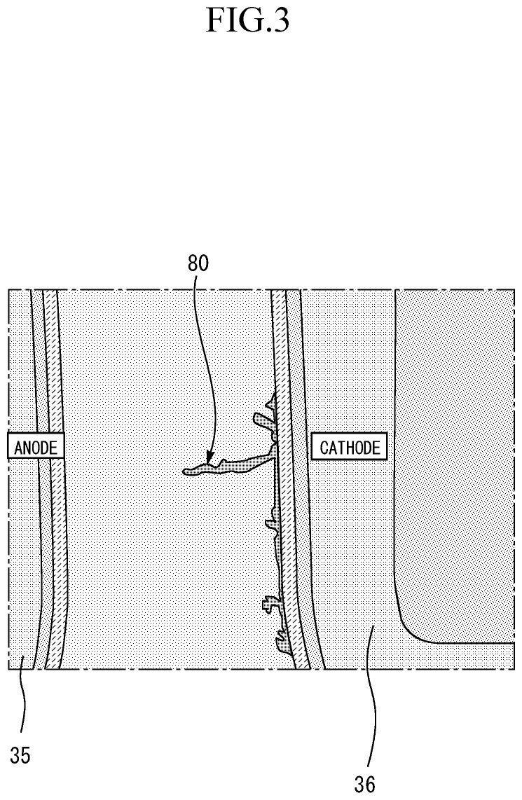

FIG. 3 is a diagram illustrating an example of a tree 80. In the example illustrated in FIG. 3, the tree 80 is generated on a cathode 36 side in a region in which the anode 35 is adjacent to the cathode 36. The check of presence or absence of the tree generation is performed by using, for example, a microscope.

When a tree is observed at step 4, the method proceeds to step 5 and discards the substrate 30. When no tree is observed at step 4, the method proceeds to step 6. In this manner, the substrate 30 is determined to be a defective product when a tree is generated in the plurality of circuit patterns 34 due to voltage application, and the substrate 30 is determined to be a non-defective product when no tree is generated.

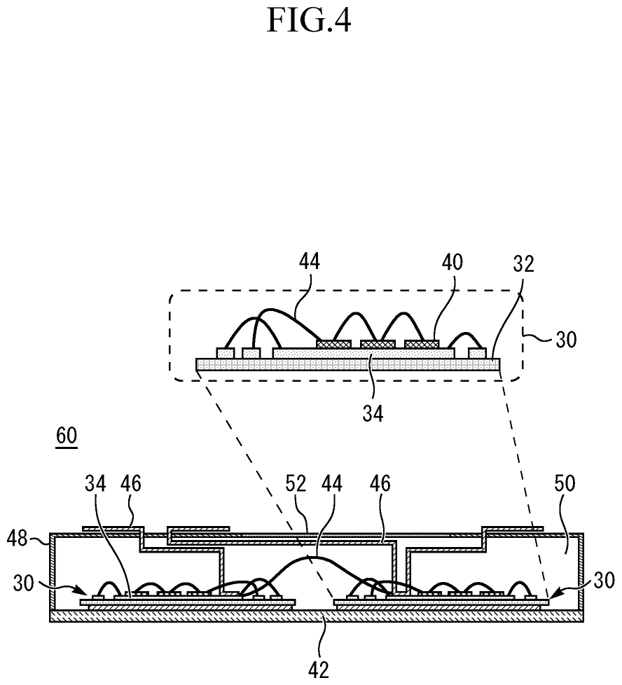

Subsequently, as step 6, the substrate 30 determined to be a non-defective product is cleaned. Subsequent processes will be described with reference to FIG. 4. FIG. 4 is a cross-sectional view of a semiconductor device 60 according to Embodiment 1. As step 7, semiconductor chips 40 are mounted on the substrate 30 determined to be a non-defective product. The semiconductor chips are, for example, power semiconductor chips. Subsequently, as step 8, the substrate 30 is mounted on a base plate 42. Subsequently, as step 9, wire bonding is performed. In the wire bonding, for example, any pair of semiconductor chips 40, any pair of a semiconductor chip 40 and circuit patterns 34, and any pair of circuit patterns 34 are connected through wires 44.

Subsequently, as step 10, terminal junction is performed. In this process, for example, terminals 46 are joined to the circuit patterns 34. Subsequently, as step 11, case junction is performed. In this process, a case 48 is joined to the base plate 42. Subsequently, as step 12, terminal bending is performed. In this process, the terminals 46 are bent. Subsequently, as step 13, gel sealing and lid closing are performed. In this process, the inside of the case 48 is sealed with a sealing body 50. In addition, a lid 52 is mounted on the case 48. Accordingly, the semiconductor device 60 is completed. The semiconductor device 60 is, for example, an electric power semiconductor device.

In the present embodiment, presence or absence of electrochemical migration occurrence can be easily checked by immersing the substrate 30 in pure water and applying voltage between the circuit patterns 34. Thus, screening can be easily performed and quality improvement can be expected. Moreover, in the present embodiment, defect detection can be performed by taking the substrate 30 out of the immersion liquid 14 and checking presence or absence a tree. Thus, further electrochemical reaction can be prevented from occurring in a process of determining defect existence. Furthermore, the defect detection can be performed in a short time.

Determining presence or absence of a tree may be performed within 330 seconds from the immersion of the substrate 30 in the immersion liquid 14. In other words, steps 1 to 4 may be performed within 330 seconds. With such fast examination, quality improvement is expected.

An electric field applied between the plurality of circuit patterns 34 by the voltage applied between the plurality of circuit patterns 34 is preferably equal to or higher than 10 V/mm. Electrochemical reaction can be caused when the electric field is equal to or higher than 10 V/mm. Accordingly, defect detection based on presence or absence of a tree can be accurately performed.

Any semiconductor chip 40 may be made with a wide bandgap semiconductor. The wide bandgap semiconductor is, for example, silicon carbide, gallium nitride material, or diamond. According to the present embodiment, it is possible to easily detect a defect in the process of manufacturing the semiconductor device 60 and improve reliability even in a case in which any semiconductor chip 40 is made with such a wide bandgap semiconductor and high current flows.

These modifications can be applied, as appropriate, to a method for manufacturing a substrate and a method for manufacturing a semiconductor device according to the following embodiment. Note that the method for manufacturing the substrate and the method for manufacturing the semiconductor device according to the following embodiment are similar to those of the first embodiment in many respects, and thus differences between the method for manufacturing the substrate and the method for manufacturing the semiconductor device according to the following embodiment and those of the first embodiment will be mainly described below.

### Embodiment 2

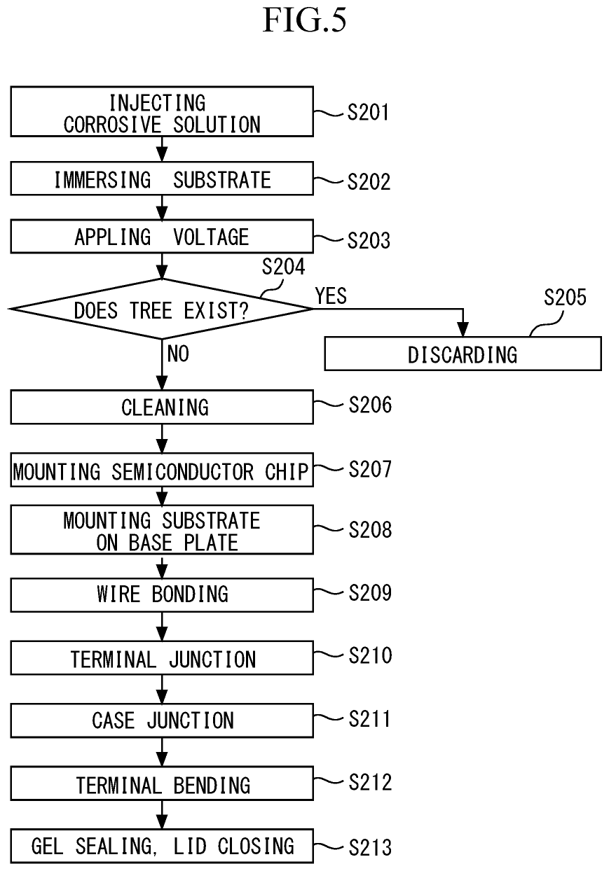

FIG. 5 is a flowchart illustrating a method for manufacturing a semiconductor device according to Embodiment 2. The present embodiment is different from Embodiment 1 in that a corrosive solution is used as the immersion liquid 14. The corrosive solution contains, for example, sulfur. Any other manufacturing process is the same as a manufacturing process of Embodiment 1.

The corrosive solution is obtained by mixing corrosive gas into pure water. Accordingly, mixture of unnecessary material can be prevented when the corrosive solution is manufactured. For example, sulfur gas, chlorine gas, or sulfurous acid gas can be used as the corrosive gas.

The method for manufacturing a semiconductor device according to the present embodiment is described below. First, as step 201, the corrosive solution is injected into the case 10. Steps 202 to 213 are the same as steps 2 to 13 of Embodiment 1, respectively.

In the present embodiment, electrochemical reaction can be activated by mixing corrosive gas into pure water. Thus, the accuracy of defect recognition can be improved.

Note that the technical features described in the above embodiments may be combined as appropriate.

### REFERENCE SIGNS LIST

10 case, 12 voltage application circuit, 14 immersion liquid, 16 external power source, 30 substrate, 32 insulating layer, 34 circuit pattern, 35 anode, 36 cathode, 40 semiconductor chip, 42 base plate 44 wire, 46 terminal, 48 case, 50 sealing body, 52 lid, 60 semiconductor device, 80 tree, 100 examination device

1. A method for manufacturing a substrate, the method comprising:
immersing a substrate on which a plurality of circuit patterns are formed in pure water or a corrosive solution;
applying voltage between the plurality of circuit patterns in a state in which the substrate is immersed in the pure water or the corrosive solution; and
determining the substrate to be a defective product when a tree is generated in the plurality of circuit patterns due to the voltage application and determining the substrate to be a non-defective product when the tree is not generated.

2. The method for manufacturing a substrate according to claim 1, wherein
the substrate is immersed in the corrosive solution, and
the corrosive solution is obtained by mixing corrosive gas into pure water.

3. The method for manufacturing a substrate according to claim 1, wherein the corrosive solution contains sulfur.

4. The method for manufacturing a substrate according to claim 1, wherein an electric field applied between the plurality of circuit patterns by the voltage is equal to or higher than 10 V/mm.

5. The method for manufacturing a substrate according to claim 1, wherein determining presence or absence of the tree is performed within 330 seconds from the substrate immersion in the pure water or the corrosive solution.

6. A method for manufacturing a semiconductor device, the method comprising:
immersing a substrate on which a plurality of circuit patterns are formed in pure water or a corrosive solution;
applying voltage between the plurality of circuit patterns in a state in which the substrate is immersed in the pure water or the corrosive solution;
determining the substrate to be a defective product when a tree is generated in the plurality of circuit patterns due to the voltage application and determining the substrate to be a non-defective product when the tree is not generated; and
mounting a semiconductor chip on the substrate determined to be a non-defective product.

7. The method for manufacturing a semiconductor device according to claim 6, wherein the semiconductor chip is made with wide bandgap semiconductor.

8. The method for manufacturing a semiconductor device according to claim 7, wherein the wide bandgap semiconductor is silicon carbide, gallium-nitride-based material or diamond.
